(19) United States
(12) Patent Application Publication
(10) Pub. No.: US 2009/0096008 A1
(43) Pub. Date: Apr. 16, 2009

(54) NONVOLATILE MEMORY DEVICE AND METHOD OF FABRICATING THE SAME

(75) Inventors: Sun-jung Kim, Gyeonggi-do (KR); Young-geun Park, Gyeonggi-do (KR); Han-mei Choi, Seoul (KR); Seung-hwan Lee, Gyeonggi-do (KR); Se-hoon Oh, Gyeonggi-do (KR); Young-sun Kim, Gyeonggi-do (KR); Sung-tae Kim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/249,004

(22) Filed: Oct. 10, 2008

(30) Foreign Application Priority Data
Oct. 10, 2007 (KR) 10-2007-0102584

(51) Int. Cl. H01L 29/788; H01L 23/58

(52) U.S. Cl. 257/316; 257/649; 257/E29.3

(57) ABSTRACT

A nonvolatile memory device having a blocking insulating layer with an excellent data retention property and a method of fabricating the same are provided. The nonvolatile memory device may include a semiconductor substrate having a channel region formed therein; and a gate stack including a tunneling insulating layer, a charge storing layer, a blocking insulating layer and a control gate electrode sequentially stacked on the channel region of the semiconductor substrate. The blocking insulating layer may comprise a lanthanum aluminum oxide having a formula of La₂₋ₓAlₓO_{y} and the composition parameter x may be 1<x<2.

### CROSS-REFERENCE TO RELATED PATENT APPLICATION

This application claims the benefit of Korean Patent Application No. 10-2007-0102584, filed on Oct. 11, 2007, in the Korean Intellectual Property Office, the disclosure of which is incorporated herein in its entirety by reference.

### BACKGROUND OF THE INVENTION

1. Field of the Invention

The present invention relates to a nonvolatile memory device and a method of fabricating the same, and more particularly, to a nonvolatile memory device having a blocking insulating layer and a method of fabricating the same.

2. Description of the Related Art

A nonvolatile memory device is a memory device in which stored information can be maintained even though a power supply is blocked. Recently, as demands on portable multimedia players, digital cameras, PDAs and the like increase, research and development on large-sized and high-integration memory devices applied to these electronic devices has been rapidly advanced.

Flash memories are widely applied as nonvolatile memory devices. A charge trap nonvolatile memory device using a silicon-oxide-nitride-oxide-silicon gate stack is a representative example of a flash memory. The SONOS memory device substitutes for a conventional floating gate-type nonvolatile memory device because of its low programming voltage, smaller size of cells and superior durability of tunneling oxide.

In such a nonvolatile memory device, a blocking insulating layer is required to have a sufficient thickness and bandgap to such a degree that both tunneling from a control gate to a charge storing layer and tunneling from the charge storing layer to a control gate can be prevented. In addition, as the nonvolatile memory device is continuously scaled down, and an operation voltage is decreased by a level of a voltage which can be applied to a logic circuit, the blocking insulating layer is required to have a high dielectric constant for increasing durability of the tunneling oxide and enhancing coupling efficiency.

As such, the blocking insulating layer is required to have a large bandgap and a high dielectric constant. However, the bandgap of the insulating substance generally tends to decrease as the dielectric constant of insulating substance increases. Therefore, studies on a candidate substance that has a sufficient bandgap as well as a high dielectric constant are required in order to develop a candidate blocking insulating layer. In order to apply the candidate substance as a blocking insulating layer, the candidate substance is required to have good thermal stability that the candidate substance is not deteriorated by a thermal budget generated in a subsequent process, as well as properties such as a high dielectric constant and a large bandgap.

### SUMMARY OF THE INVENTION

The present invention provides a nonvolatile memory device which includes a blocking insulating layer made of a candidate substance that has superior properties such as a high dielectric constant and a broad bandgap and is not deteriorated by a thermal budget generated in a subsequent process.

The present invention also provides a method of fabricating a nonvolatile memory device including a blocking insulating layer made of the candidate substance.

According to an aspect of the present invention, there is provided a nonvolatile memory device, which includes: a semiconductor substrate having a channel region formed therein; and a gate stack including a tunneling insulating layer, a charge storing layer, a blocking insulating layer and a control gate electrode sequentially stacked on the channel region of the semiconductor substrate. The blocking insulating layer may comprise a lanthanum aluminum oxide having a formula of La₂₋ₓAlₓO_{y} and the composition parameter x may be 1<x<2.

In some embodiments, the composition parameter x may be 1.005≦x≦1.8. Further, in some embodiments, the tunneling insulating layer may include any one of a silicon oxide, a silicon nitride and a silicon-oxy-nitride, or a combination of them. Optionally, the tunneling insulating layer may further include nano-crystal particles therein.

The charge storing layer may be a floating gate. Alternatively, the charge storing layer may be a charge trapping layer. In some embodiments, the charge trapping layer may be formed of any one of a silicon nitride, a silicon oxide, a hafnium oxide, a zirconium oxide, a tantalum oxide, a titanium oxide, a hafnium aluminum oxide, a hafnium tantalum oxide, a hafnium silicon oxide, an aluminum nitride and an aluminum gallium nitride, or a combination thereof. Further, the charge trapping layer may include quantum dots therein.

In the nonvolatile memory device according to the aspect of the present invention, a lanthanum aluminum oxide in which the content of Al is higher than that of La is used as a blocking insulating layer, so that the nonvolatile memory device can have excellent thermal stability even in subsequent high-temperature processes, and thus, can have an excellent data retention property.

According to another aspect of the present invention, there is provided a method of fabricating a nonvolatile memory device, which may include: providing a semiconductor substrate having a channel region formed therein; and forming a gate stack including a tunneling insulating layer, a charge storing layer, a blocking insulating layer and a control gate electrode sequentially stacked on the channel region of the semiconductor substrate. The blocking insulating layer may comprise a lanthanum aluminum oxide having a formula of La₂₋ₓAlₓO_{y} and the composition parameter may be 1<x<2. In some embodiments, the composition parameter x may be 1.005≦x≦1.8 in the formula of the lanthanum aluminum oxide.

In a nonvolatile memory device according to embodiments of the present invention, a lanthanum aluminum oxide in which the content of Al is higher than that of La is used as a blocking insulating layer, so that the nonvolatile memory device can have excellent thermal stability even in subsequent high-temperature processes, and thus, can have an excellent data retention property.

Further, according to embodiments of the present invention, there can be provided a method of fabricating a nonvolatile memory device having the blocking insulating layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a cell of a nonvolatile memory device having a gate stack according to an embodiment of the present invention;

FIGS. 2A and 2B are cross-sectional views of cells of nonvolatile memory devices having gate stacks according to another embodiment of the present invention; and

FIG. 3 is a graph illustrating leakage current characteristics of a nonvolatile memory device according to an embodiment of the present invention and an experimental group.

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the following description, an expression that an element such as a layer, region, substrate or plate is placed on or above another element indicates not only a case where the element is placed directly on or just above the other element but also a case where a further element is interposed between the element and the other element. Further, in the drawings, the thickness of layers, films and regions are exaggerated for clarity. Like numbers refer to like elements throughout the specification. As used herein the expression “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present invention will be described with reference to the accompanying drawings. In the drawings, modifications may be expected depending on fabrication technology and/or tolerance, for example. Accordingly, the embodiments of the present invention are not limited to a specific shape illustrated in the specification but may include, for example, a change in shape caused by a fabrication process.

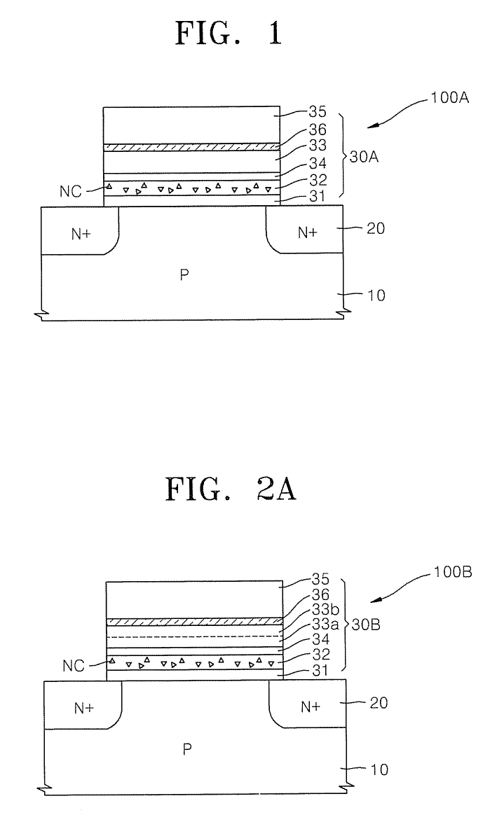

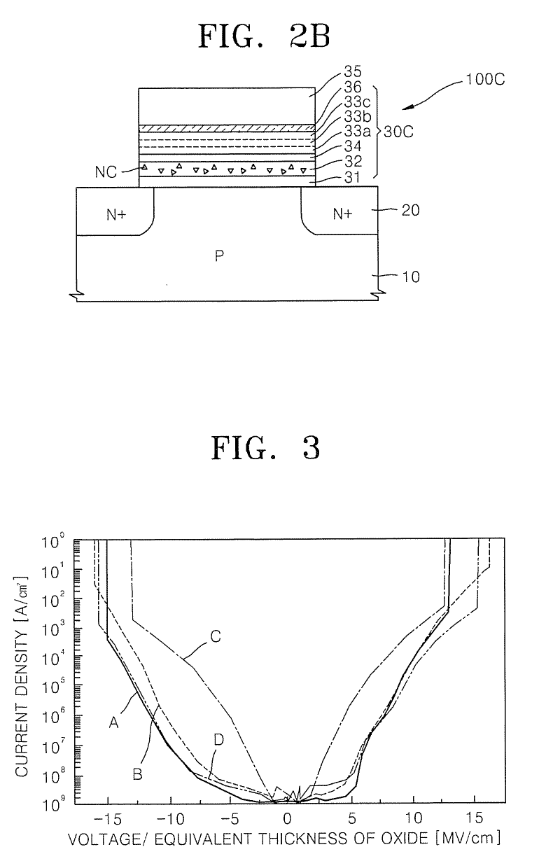

FIG. 1 is a cross-sectional view of a cell of a nonvolatile memory device 100A having a gate stack 30A according to an embodiment of the present invention. FIGS. 2A and 2B are cross-sectional views of cells of nonvolatile memory devices 100B and 100C having gate stacks 30B and 30C according to another embodiment of the present invention. Memory cells having the illustrated structures are arranged in a predetermined array form, thereby implementing nonvolatile memory devices. An array having a plurality of cells may provide a NAND or NOR flash memory device, for example.

Referring to FIG. 1, the cell of the nonvolatile memory device 100A includes a gate stack 30A formed into a multi-layer structure stacked on a semiconductor substrate 10 having a channel region formed therein. Source/drain regions 20 spaced apart by the gate stack 30A are disposed at both ends of the channel region. The gate stack 30A includes a tunneling insulating layer 31 formed between the channel region and a charge storing layer 32 and a blocking insulating layer 33 formed between the charge storing layer 32 and a control gate 34.

The semiconductor substrate 10 may be a commercially available semiconductor substrate. For example, the semiconductor substrate 10 may include a bulk silicon semiconductor substrate, a silicon-on-insulator (SOI) substrate, a silicon-on-sapphire (SOS) substrate or a semiconductor substrate made of another material known in the art. The semiconductor substrate 10 may have a P type. The gate stack 30a may be formed on the semiconductor substrate 10 and then the source/drain regions 20 may be formed by performing an N-type impurity implantation process using the gate stack 30A as an ion implantation mask, and then performing an annealing process for activating impurities. A spacer forming process may be further performed after forming the gate stack 30A.

The tunneling insulating layer 31 provides a passage for charges transferred between the charge storing layer 32 and the semiconductor substrate 10 according to a programming method of the nonvolatile memory device, e.g., a hot carrier injection or Fowler-Nordheim tunneling. For example, the tunneling insulating layer 31 may be a silicon oxide (SiO₂) having a thickness of 30 to 80 Å. In other embodiments, the tunneling insulating layer 31 may include a silicon-oxy-nitride (SiON) or a composite layer such as a silicon oxide (SiO₂)/silicon nitride (Si₃N₄), a silicon oxide (SiO₂)/nano-crystal particles/silicon oxide (SiO₂), or the like.

The charge storing layer 32 may be formed of, for example, poly silicon to implement a floating gate. In other embodiments, the charge storing layer 32 may be a charge trapping layer. A silicon nitride having a thickness of 30 to 150 Å may be used to implement a SONOS memory device as the charge trapping layer. However, this is provided only for illustrative purposes and the present invention should not be limited thereto. For example, the charge trapping layer may be formed of any one of a silicon oxide, a hafnium oxide, a zirconium oxide, a tantalum oxide, a titanium oxide, a hafnium aluminum oxide, a hafnium tantalum oxide, a hafnium silicon oxide, an aluminum nitride and an aluminum gallium nitride, or a combination of at least two of them.

In order to increase integration density of the memory device, the charge storing layer 32 may have a plurality of quantum dots NC contained therein. As used herein, the term “quantum dots” generally denote material dots formed at the atom size level, but it is practically difficult to form the quantum dot at the atom size level. For this reason, the term “quantum dot” also means a charge trapping element larger than the atom size level, e.g., a nano-crystal having a diameter of 20 to 30 nm.

The quantum dot NC may include, for example, a silicon-quantum dot, a germanium-quantum dot, a tin-quantum dot, a gold-quantum dot or the like. For example, the quantum dots with a predetermined size may be formed by implanting metal ions into an oxide layer or nitride layer and then performing appropriate heat treatment on the metal ions to grow them. Alternatively, the quantum dots may be formed by forming a thin metal layer on an oxide layer or nitride layer using a chemical vapor deposition method, stacking again an oxide layer or nitride layer covering the metal layer, and then performing heat treatment.

Referring to FIGS. 2A and 2B together with FIG. 1, the blocking insulating layer 33a, 33b and 33c include a lanthanum aluminum oxide with a high dielectric constant and a wide bandgap, having a formula of La₂₋ₓAlₓO_{y}. Here, the parameters x and y are composition parameters that denote molar ratios of La, Al and O. In the embodiments of the present invention, since the composition parameter x is 1<x<2, Al is more contained in the lanthanum aluminum oxide than La. The lanthanum aluminum oxide may be a compound substance of LaAlO₃ and Al₂O₃ having various microstructures. For example, LaAlO₃ crystals may be precipitated from the stoichiometric compound of LaAlO₃ and Al₂O₃. Alternatively, the lanthanum aluminum oxide may have an amorphous structure in which Al is more contained than La. These examples are not intended to limit the invention.

The blocking insulating layer 33 according to an embodiment of the present invention may be formed into a single layer structure of the lanthanum aluminum oxide as illustrated in FIG. 1. Alternatively, the blocking insulating layer 33 may be formed into a stacked structure of an aluminum oxide 33a and a lanthanum aluminum oxide 33b as illustrated in FIG. 2A. Alternatively, the blocking insulating layer 33 may be formed into a stacked structure of aluminum oxide 33a/lanthanum aluminum oxide 33b/aluminum oxide 33c as illustrated in FIG. 2B. In the stacked structure, it will be apparent that the stacking order of the aluminum oxide and the lanthanum aluminum oxide may be modified without departure from the scope of the present invention. From experiment, it can be found that the lanthanum aluminum oxide according to embodiments of the present invention has superior properties as a blocking insulating layer because it has a dielectric constant of about 25 and an energy bandgap of about 6.5 eV. When the blocking insulating layer 33 further includes an aluminum oxide as described above, the composition ratio of Al and La may be maintained at the substantially equal level in the lanthanum aluminum oxide 33b.

As described later with reference to FIG. 3, when the content of Al is higher than that of La in the lanthanum aluminum oxide, excellent thermal stability can be secured against a thermal budget caused by subsequent high-temperature processes, e.g., an annealing process for activating source/drain regions. In some embodiments, the composition parameter may be 1.005≦x≦1.8. In this case, the composition ratio of Al:La is about 1:0.99 to 1:0.11. In some embodiments, the content of oxygen may be larger than that of Al and La, based on the stoichiometric ratio of the lanthanum aluminum oxide. That is, the composition parameter y of oxygen may be greater than 3. In this case, the composition parameter y is 4 or less. If the content of oxygen is rich, La and/or Al metal islands are not formed within the lanthanum aluminum oxide even in the subsequent high-temperature processes, and therefore, it can be expected that excellent properties as an insulating layer can be maintained. As well known in the art, the aforementioned composition parameters x and y can be obtained by Auger electron spectroscopy (AES) analysis.

The blocking insulating layer 33 may be formed, for example, by an atomic layer deposition (ALD) method, a chemical vapor deposition (CVD) method and a physical vapor deposition (PVD) method such as sputtering. Among them, the ALD method has an advantage in that thin film deposition is possible at a low temperature, and a composition ratio is easily adjusted. For example, the lanthanum aluminum oxide may be formed by alternately growing Al₂O₃ and La₂O₃ layers with different thicknesses using a trimethyl aluminum (TMA; Al(CH₃O)₃) precursor containing Al, a trisethycyclropentadienato lanthanum (La(EtCp)₃) precursor containing La and an oxygen-containing gas such as oxygen or ozone, and, if necessary, performing a diffusion process through heat treatment. In this case, the thickness of the Al₂O₃ layer may be thicker than that of the La₂O₃ layer.

From experiments of the present inventor, it can be seen that the number of supply pulses or the supply time of a La precursor is longer than those of an Al precursor in order to grow the lanthanum aluminum oxide, in which the composition ratio of La and Al is 1:1, by the ALD method. This means that the deposition speed of the La precursor is slower than that of the Al precursor. For example, the lanthanum aluminum oxide, in which the composition ratio of La and Al is 1:1, can be experimentally grown by making a basic cycle and repeating the basic cycle. In the basic cycle, an aluminum oxide deposition unit cycle including Al supply/purge/O supply/purge and a lanthanum oxide deposition unit cycle including La supply/purge/O supply/purge are combined at a ratio of 1:3.

Thus, the lanthanum aluminum oxide may be grown by repeating a basic cycle. In the basic cycle, the number of lanthanum oxide deposition unit cycles is smaller than that of aluminum oxide deposition unit cycles for forming the lanthanum aluminum oxide in which the composition ratio of La and Al is 1:1, e.g., the number of aluminum oxide deposition unit cycles:the number of lanthanum oxide deposition unit cycles may be 1:1, 1:2, 2:4, 2:5, 3:5, 3:6 or the like. Alternatively, the lanthanum aluminum oxide in which the content of Al is higher than that of La may be grown by repeating a basic cycle. In the basic cycle, the number of aluminum oxide deposition unit cycles may be greater than that of aluminum oxide deposition unit cycles for forming the lanthanum aluminum oxide in which the composition ratio of La and Al is 1:1.

In addition, proper metal-organic precursor materials respectively containing La and Al, e.g. TMA, LA(EtCp)₃ and the oxygen-containing gas, may be provided at an appropriate partial pressure ratio, thereby forming the blocking insulating layer using the CVD method. The flow rate of the precursor containing Al may be greater than that of the precursor containing La, thereby growing the lanthanum aluminum oxide in which the content of Al is higher than that of La.

The blocking insulating layer 33 may be formed by simultaneously sputtering Al and La targets under an oxygen atmosphere. The bias of the La target may be increased more than that of the Al target, thereby growing the lanthanum aluminum oxide in which the content of Al is higher than that of La.

In some embodiments, a diffusion barrier 34 having a thickness of 20 to 50 Å may be formed on the charge storing layer 32 before forming the blocking insulating layer 33. For example, the diffusion barrier 34 may be formed of any one of a silicon nitride, a silicon oxide, a hafnium oxide, a zirconium oxide, a tantalum oxide, a titanium oxide, a hafnium aluminum oxide, a hafnium tantalum oxide, a hafnium silicon oxide, an aluminum nitride and an aluminum gallium nitride, or a combination of them.

The control gate 35 may be formed of a conductive layer having a thickness of 500 to 3000 Å, e.g., a poly-silicon layer or a tungsten nitride. In some embodiments, a buffer layer 36 such as a tantalum nitride may be disposed between the blocking insulating layer 33 and the control gate 35.

Generally, a gate stack 30 may be formed by sequentially stacking the aforementioned insulating layers 31, 32, 33, 34, 35 and 36 on the channel region of the semiconductor substrate 10 and then patterning them. Thereafter, as described above, impurities may be implanted into the semiconductor substrate 10 using the gate stack 30 as an ion implantation mask, thereby forming the source/drain regions at both ends of the channel region. In order to activate the implanted impurities, an annealing process that is a high-temperature process may be performed. Hereinafter, the relation between the composition ratio of La/Al of the lanthanum aluminum oxide according the embodiments of the present invention and the annealing process will be described.

FIG. 3 is a graph illustrating leakage current characteristics of a nonvolatile memory device according to an embodiment of the present invention and an experimental group. In the experimental group, a silicon substrate/silicon oxide having a thickness of 40 Å/nitride oxide having a thickness of 70 Å is used as a semiconductor substrate/tunneling insulating layer/charge storing layer. An annealing process for forming source/drain regions is performed at 750° C. for two minutes. The abscissa indicates a ratio of an applied voltage and the thickness of an equivalent oxide, and the ordinate indicates a current density.

Curve A represents the case where the annealing process is performed on a gate stack having a blocking insulating layer made of a lanthanum aluminum oxide in which the content of Al is higher than that of La according to the embodiment of the present invention. The composition ratio of Al:La in the lanthanum aluminum oxide measured by the AES analysis is 1:0.7, i.e., the composition parameter x is 1.176.

On the other hand, curve B represents the case where the annealing process is performed on a gate stack having a blocking insulating layer made of Al₂O₃. Curve C represents the case where the annealing process is performed on a gate stack having a blocking insulating layer made of stoichiometric LaAlO₃. Curve D represents the case where the annealing process is not performed on a gate stack having a blocking insulating layer made of stoichiometric LaAlO₃.

Referring to FIG. 3, if the curve C is compared with the curve D, it can be seen that the gate stack having the blocking insulating layer made of stoichiometric LaAlO₃ has an increased leakage current due to the annealing process. It can be seen that the gate stack having the blocking insulating layer made of Al₂O₃ is not more deteriorated due to the annealing process than the gate stack having the blocking insulating layer made of stoichiometric LaAlO₃, but has a relatively great leakage current.

On the contrary, it can be seen that after performing the annealing process, the gate stack having the blocking insulating layer according to an embodiment of the present invention has leakage current characteristics equal or superior to the case where the annealing process is not performed with respect to a gate stack having a blocking insulating layer made of stoichiometric LaAlO₃.

In the aforementioned embodiment, the charge storing layer and/or blocking insulating layer are respectively formed into a single-layered structure. However, it will be apparent that an embodiment having a multi-layered structure in which another insulating layer is stacked on any one surface of the charge storing layer and/or blocking insulating layer is included in the scope of the present invention as necessary.

In addition, it will be apparent that a multi-level cell memory device having a gate stack in which at least two-layered charge storing layers are stacked to increase memory density is included in the scope of the present invention.

The present invention includes the above mentioned embodiments and other various embodiments including the following:

1) A method of fabricating a nonvolatile memory device, comprising:

providing a semiconductor substrate having a channel region formed therein; and

forming a gate stack including a tunneling insulating layer, a charge storing layer, a blocking insulating layer and a control gate electrode sequentially stacked on the channel region of the semiconductor substrate,

wherein the blocking insulating layer comprises a lanthanum aluminum oxide having a formula of La₂₋ₓAlₓO_{y} and the composition parameter x is 1<x<2.

2) A method according to the above 1), wherein the composition parameter x is 1.005≦x≦1.8.

3) A method according to the above 1), wherein the blocking insulating layer is formed by any one of an atomic layer deposition (ALD) method, a chemical vapor deposition (CVD) method and a physical vapor deposition (PVD) method.

4) A method according to the above 3), wherein the ALD method is performed by repeating a basic cycle at least once or more, the basic cycle including a combination of at least one lanthanum oxide deposition unit cycle and at least one aluminum oxide deposition unit cycle, and

wherein the composition parameter x is controlled by adjusting the number of lanthanum oxide deposition unit cycles and the number of aluminum oxide deposition unit cycles.

5) A method according to the above 1), wherein the tunneling insulating layer comprises any one of a silicon oxide, a silicon nitride and a silicon-oxy-nitride, or a combination thereof.

6) A method according to the above 1), wherein the tunneling insulating layer comprises nano-crystal particles therein.

7) A method according to the above 1), wherein the charge storing layer is a floating gate or a charge trapping layer.

8) A method according to the above 7), wherein the charge trapping layer is formed of any one of a silicon nitride, a silicon oxide, a hafnium oxide, a zirconium oxide, a tantalum oxide, a titanium oxide, a hafnium aluminum oxide, a hafnium tantalum oxide, a hafnium silicon oxide, an aluminum nitride and an aluminum gallium nitride, or a combination thereof.

9) A method according to the above 7), wherein the charge trapping layer comprises quantum dots therein.

10) A method according to the above 1), wherein the quantum dot comprises any one of a silicon-quantum dot, a germanium-quantum dot, a tin-quantum dot and a gold-quantum dot, or a combination thereof.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A nonvolatile memory device, comprising:
a semiconductor substrate having a channel region formed therein; and
a gate stack including a tunneling insulating layer, a charge storing layer, a blocking insulating layer and a control gate electrode sequentially stacked on the channel region of the semiconductor substrate, the blocking insulating layer comprising a lanthanum aluminum oxide having a formula of La₂₋ₓAlₓO_{y}, wherein the composition parameter x is 1<x<2.

2. The nonvolatile memory device of claim 1, wherein the composition parameter x is 1.005≦x≦1.8.

3. The nonvolatile memory device of claim 1, wherein the composition parameter y is 3<y≦4.

4. The nonvolatile memory device of claim 1, wherein the blocking insulating layer further includes at least one aluminum oxide.

5. The nonvolatile memory device of claim 1, wherein the tunneling insulating layer includes any one of a silicon oxide, a silicon nitride and a silicon-oxy-nitride, or a combination thereof.

6. The nonvolatile memory device of claim 1, wherein the tunneling insulating layer comprises nano-crystal particles therein.

7. The nonvolatile memory device of claim 1, wherein the charge storing layer is a floating gate or a charge trapping layer.

8. The nonvolatile memory device of claim 7, wherein the charge trapping layer comprises any one of a silicon nitride, a silicon oxide, a hafnium oxide, a zirconium oxide, a tantalum oxide, a titanium oxide, a hafnium aluminum oxide, a hafnium tantalum oxide, a hafnium silicon oxide, an aluminum nitride and an aluminum gallium nitride, or a combination thereof.

9. The nonvolatile memory device of claim 7, wherein the charge trapping layer comprises quantum dots therein.

10. The nonvolatile memory device of claim 9, wherein the quantum dot comprises any one of a silicon-quantum dot, a germanium-quantum dot, a tin-quantum dot and a gold-quantum dot, or a combination thereof.
